(19) United States
(12) Patent Application Publication
(10) Pub. No.: US 2025/0347002 A1
(43) Pub. Date: Nov. 13, 2025

(54) SUBSTRATE PROCESSING METHOD AND SUBSTRATE PROCESSING SYSTEM

(71) Applicant: Tokyo Electron Limited, Tokyo (JP)

(72) Inventors: Koji AKIYAMA, Yamanashi (JP); Kotaro SATO, Yamanashi (JP); Mitsuaki IWASHITA, Yamanashi (JP); Hirokazu UEDA, Osaka City (JP)

(21) Appl. No.: 19/270,815

(22) Filed: Jul. 16, 2025

Related U.S. Application Data
(63) Continuation of application No. PCT/JP2024/000298, filed on Jan. 10, 2024.

(30) Foreign Application Priority Data
Jan. 17, 2023 (JP) 2023-005409

(51) Int. Cl. C23C 18/52; C23C 22/82

(52) U.S. Cl. CPC C23C 18/52; C23C 22/82

(57) ABSTRACT

A substrate processing method includes: preparing a substrate in which patterns of a conductor and an insulator are formed in a substrate surface of the substrate; coating the substrate surface of the substrate with an ionic liquid including a metal salt; and applying energy to the substrate coated with the ionic liquid. The applying the energy to the substrate includes forming a metal layer on a surface of the conductor by precipitating a metal of the metal salt on the surface of the conductor by a reduction reaction of the metal salt.

### CROSS-REFERENCE TO RELATED APPLICATIONS

This application is a bypass continuation application of International Application No. PCT/JP2024/000298 having an international filing date of Jan. 10, 2024 and designating the United States, the international application being based upon and claiming the benefit of priority from Japanese Patent Application No. 2023-005409, filed on Jan. 17, 2023, the entire contents of which are incorporated herein by reference.

### TECHNICAL FIELD

The present disclosure relates to a substrate processing method and a substrate processing system.

### BACKGROUND

Patent Document 1 discloses a technique for embedding a metal layer in a trench formed in an insulating film and then etching away a surface portion of the metal layer, thereby positioning an upper surface of the metal layer downward of an upper surface of the insulating film.

### PRIOR ART DOCUMENTS

### Patent Documents

Patent Document 1: Japanese Patent Laid-Open Publication No. 2019-061978

### SUMMARY

According to one embodiment of the present disclosure, a substrate processing method includes preparing a substrate in which patterns of a conductor and an insulator are formed in a substrate surface of the substrate; coating the substrate surface of the substrate with an ionic liquid including a metal salt; and applying energy to the substrate coated with the ionic liquid, wherein the applying the energy to the substrate includes forming a metal layer on a surface of the conductor by precipitating a metal of the metal salt on the surface of the conductor by a reduction reaction of the metal salt.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating an example of a configuration of a substrate processing system according to an embodiment.

FIG. 2 is a schematic view illustrating an example of a coating apparatus.

FIG. 3 is a schematic view illustrating an example of an energy supply apparatus.

FIG. 4 is a schematic view illustrating another example of the energy supply apparatus.

FIG. 5 is an example of a flowchart illustrating substrate processing according to a first embodiment and a second embodiment.

FIG. 6A is an example of a schematic cross-sectional view of a substrate W in each Operation of the substrate processing according to the first embodiment.

FIG. 6B is an example of a schematic cross-sectional view of the substrate W in each Operation of the substrate processing according to the first embodiment.

FIG. 6C is an example of a schematic cross-sectional view of the substrate W in each Operation of the substrate processing according to the first embodiment.

FIG. 7A is a schematic view illustrating a reaction between a metal salt and a reductant.

FIG. 7B is a schematic view illustrating a reaction between the metal salt and the reductant.

FIG. 8 is a schematic view illustrating another example of a configuration of the substrate processing system according to an embodiment.

FIG. 9 is a schematic view illustrating an example of an oxide film removing apparatus.

FIG. 10 is an example of a flowchart illustrating substrate processing according to a third embodiment and a fourth embodiment.

FIG. 11A is an example of a schematic cross-sectional view of a substrate W in each Operation of the substrate processing according to the third embodiment and the fourth embodiment.

FIG. 11B is an example of a schematic cross-sectional view of the substrate W in each Operation of the substrate processing according to the third embodiment and the fourth embodiment.

FIG. 11C is an example of a schematic cross-sectional view of the substrate W in each Operation of the substrate processing according to the third embodiment and the fourth embodiment.

FIG. 12 is an example of a flowchart illustrating substrate processing according to a fifth embodiment and a sixth embodiment.

FIG. 13A is an example of a schematic cross-sectional view of a substrate W in each Operation of the substrate processing according to the fifth embodiment and the sixth embodiment.

FIG. 13B is an example of a schematic cross-sectional view of the substrate W in each Operation of the substrate processing according to the fifth embodiment and the sixth embodiment.

FIG. 13C is an example of a schematic cross-sectional view of the substrate W in each Operation of the substrate processing according to the fifth embodiment and the sixth embodiment.

FIG. 14 is a schematic cross-sectional view illustrating an example of a structure formed in a substrate.

FIG. 15A is a perspective view illustrating another example of a structure formed in a substrate.

FIG. 15B is a perspective view illustrating another example of the structure formed in the substrate.

FIG. 16 is a perspective view illustrating an example of a structure of a metal wiring formed in the substrate.

FIG. 17A is an example of a perspective view of a substrate W in each Operation.

FIG. 17B is an example of a perspective view of the substrate W in each Operation.

FIG. 17C is an example of a perspective view of the substrate W in each Operation.

FIG. 17D is an example of a perspective view of the substrate W in each Operation.

### DETAILED DESCRIPTION

Hereinafter, embodiments for implementing the present disclosure will be described with reference to the drawings. In the respective drawings, the same components may be denoted by the same reference numerals, and duplicate descriptions thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Substrate Processing System 100]

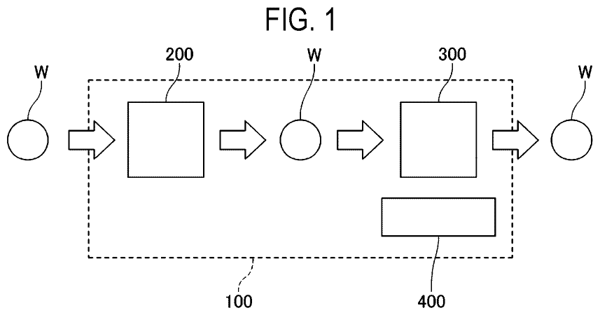

A substrate processing system 100 according to an embodiment will be described with reference to FIG. 1. FIG. 1 is a schematic view illustrating an example of a configuration of the substrate processing system 100 according to this embodiment.

The substrate processing system 100 includes a coating apparatus 200, an energy supply apparatus 300, and a control device 400.

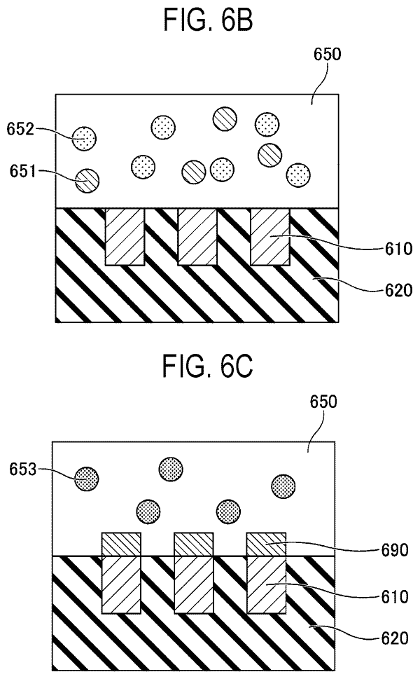

A substrate W (see FIG. 6A and the like, which will be described later) in which patterns of a conductor and an insulator are formed on a surface thereof is loaded into the coating apparatus 200. The coating apparatus 200 coats the substrate surface of the substrate W with an ionic liquid including at least one metal salt.

The substrate W having the surface coated with the ionic liquid in the coating apparatus 200 is transferred to the energy supply apparatus 300. The energy supply apparatus 300 supplies energy to the substrate W coated with the ionic liquid, so that the metal salt undergoes a reduction reaction and a metal of the metal salt is precipitated on a surface of the conductor. Thus, a metal layer is formed on the surface of the conductor. That is, a metal pattern of the metal layer is formed on the substrate surface of the substrate W so as to correspond to the pattern of the conductor. The substrate W on which the metal pattern of the metal layer is formed on the surface thereof is unloaded from the energy supply apparatus 300.

The control device 400 controls the coating apparatus 200, the energy supply apparatus 300, and the like, thereby controlling the entire operation of the substrate processing system 100.

### [Coating Apparatus 200]

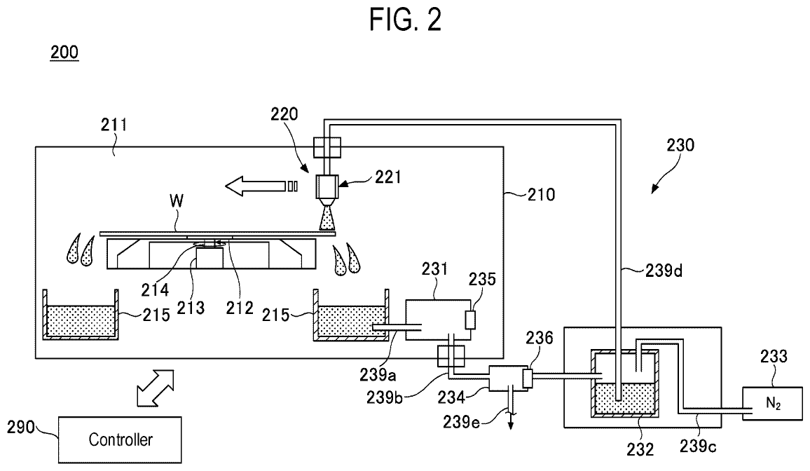

Next, an example of the coating apparatus 200 will be described with reference to FIG. 2. FIG. 2 is a schematic view illustrating an example of the coating apparatus 200. Here, a slit coater will be described as an example of the coating apparatus 200.

The coating apparatus 200 includes a chamber 210, a liquid supply 220, a liquid circulator 230, and a controller 290.

The chamber 210 is provided with a sealed processing space 211 that accommodates the substrate W therein. A stage 212 is provided inside the chamber 210. The stage 212 holds the substrate W substantially horizontally. The stage 212 is connected to an upper end of a rotary shaft 214 rotated by a drive mechanism 213, and is configured to be rotatable. A liquid collector 215 having an open upper end is provided at a lower periphery of the stage 212. The liquid collector 215 receives and stores the ionic liquid which is being dropped from or is shaken off from the substrate W. An interior of the chamber 210 is exhausted by an exhaust system (not illustrated) including a pressure control valve, a vacuum pump, and the like.

The liquid supply 220 includes a slit nozzle 221. The slit nozzle 221 moves horizontally above the substrate W to supply an ionic liquid for dry prevention from the liquid circulator 230 to the substrate surface of the substrate W placed on the stage 212.

The liquid circulator 230 collects the ionic liquid stored in the liquid collector 215 and supplies the same to the slit nozzle 221. The liquid circulator 230 includes a compressor 231, an original liquid tank 232, a carrier gas source 233, a cleaner 234, and pH sensors 235 and 236.

The compressor 231 is connected to the liquid collector 215 via a pipe 239a, and collects the ionic liquid stored in the liquid collector 215 and compresses the same to an atmospheric pressure or higher. The compressor 231 is connected to the original liquid tank 232 via a pipe 239b, and transports the compressed ionic liquid to the original liquid tank 232 via the pipe 239b. For example, a valve and a flow rate controller (both not illustrated) are provided in the pipe 239a. For example, by controlling opening/closing of the valve, the transport of the ionic liquid from the compressor 231 to the original liquid tank 232 is periodically performed.

The original liquid tank 232 stores the ionic liquid. One ends of pipes 239b to 239d are inserted into the original liquid tank 232. The other end of the pipe 239b is connected to the compressor 231 such that the ionic liquid compressed by the compressor 231 is supplied to the original liquid tank 232 via the pipe 239b. The other end of the pipe 239c is connected to the carrier gas source 233 such that a carrier gas such as a nitrogen (N₂) gas from the carrier gas source 233 is supplied to the original liquid tank 232 via the pipe 239c. The other end of the pipe 239d is connected to the slit nozzle 221 such that the ionic liquid in the original liquid tank 232 is transported together with the carrier gas to the slit nozzle 221 via the pipe 239d. For example, a valve and a flow rate controller (both not illustrated) are provided in each of the pipes 239b to 239d.

The carrier gas source 233 is connected to the original liquid tank 232 via the pipe 239c to supply the carrier gas such as a N₂ gas to the original liquid tank 232 via the pipe 239c.

The cleaner 234 is provided in the pipe 239b. The cleaner 234 cleans the ionic liquid transported from the compressor 231. A drain pipe 239e is connected to the cleaner 234 such that the ionic liquid with deteriorated properties is discharged via the drain pipe 239e. For example, the cleaner 234 controls whether or not to reuse or discharge the ionic liquid, based on a detection value of the pH sensor 236. Further, for example, the cleaner 234 may control whether or not to reuse or discharge the ionic liquid, based on a detection value of the pH sensor 235. Further, for example, the cleaner 234 may control whether or not to reuse or discharge the ionic liquid, based on the detection values of the pH sensor 235 and the pH sensor 236.

The pH sensor 235 is provided in the compressor 231 to detect a hydrogen ion exponent (pH) of the ionic liquid in the compressor 231.

The pH sensor 236 is provided in the cleaner 234 to detect a hydrogen ion exponent (pH) of the ionic liquid in the cleaner 234.

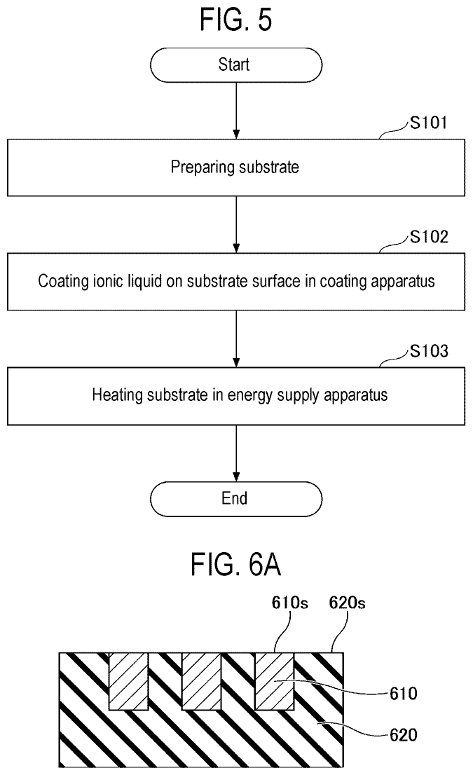

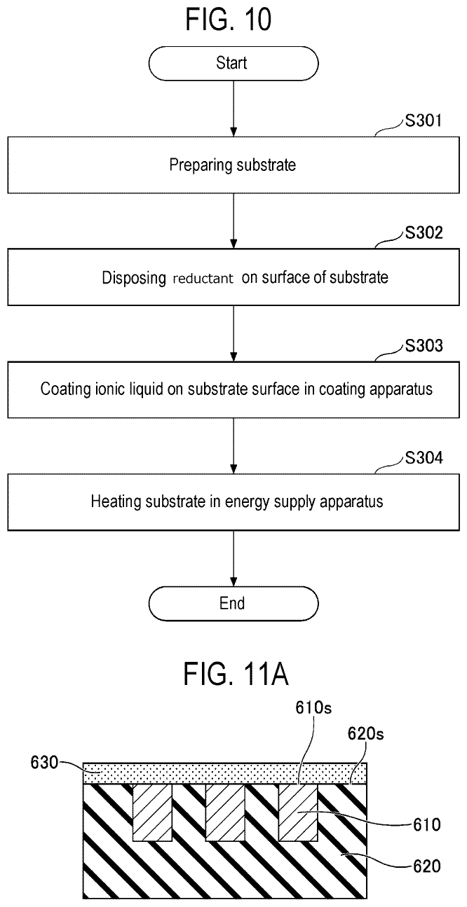

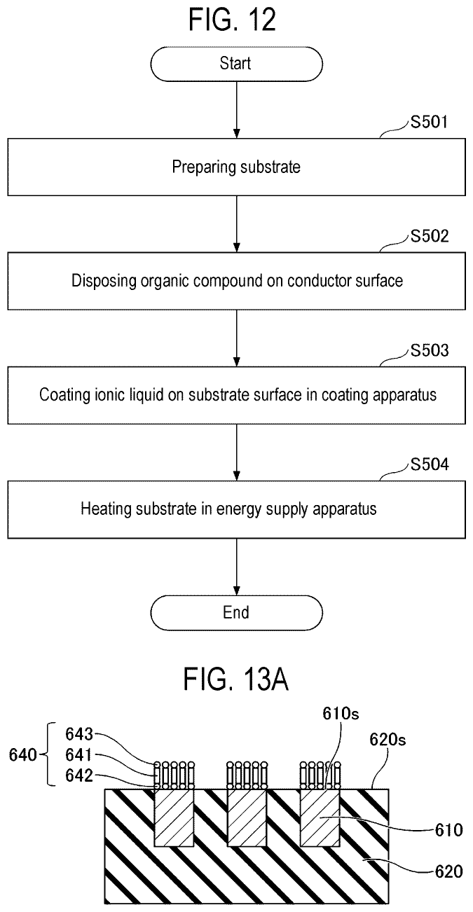

The controller 290 processes computer-executable commands that cause the coating apparatus 200 to execute operations of coating the ionic liquid (see Operation S102 of FIG. 5, Operation S303 of FIG. 10, and Operation S503 of FIG. 12), which will be described later. The controller 290 may be configured to control individual components of the coating apparatus 200 to execute the operations of coating the ionic liquid. The controller 290 includes, for example, a computer. The computer includes, for example, a CPU, a storage, and a communication interface.

### [Energy Supply Apparatus 300]

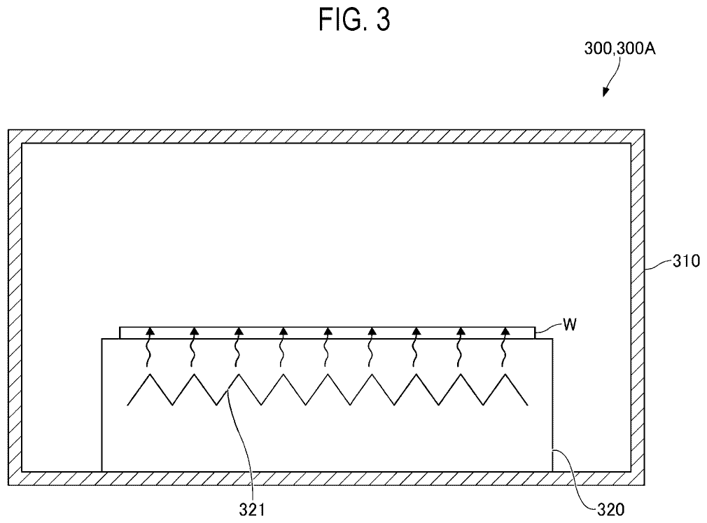

Next, an example of the energy supply apparatus 300 will be described with reference to FIG. 3. FIG. 3 is a schematic view illustrating an example of the energy supply apparatus 300. Here, a substrate heating apparatus 300A will be described as an example of the energy supply apparatus 300.

The substrate heating apparatus 300A includes a chamber 310 and a stage 320. A heater 321 is provided in the stage 320.

Accordingly, the substrate heating apparatus 300A is capable of heating the entire substrate W placed on the stage 320 from the outside.

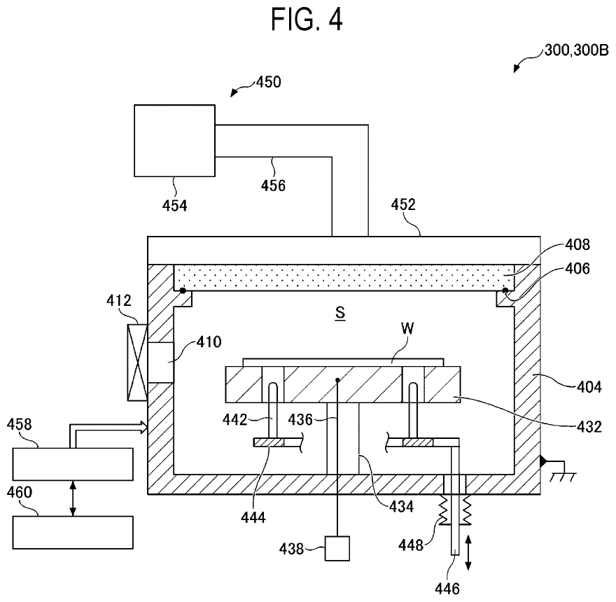

Next, another example of the energy supply apparatus 300 will be described with reference to FIG. 4. FIG. 4 is a schematic view illustrating another example of the energy supply apparatus 300. Here, a microwave irradiation apparatus 300B will be described as an example of the energy supply apparatus 300.

As illustrated in FIG. 1, the microwave irradiation apparatus 300B includes, for example, a processing container 404 molded in a cylindrical shape by a metal such as stainless steel, aluminum, or an aluminum alloy. An inner surface of the processing container 404 is mirror-finished such that introduced electromagnetic waves are easily reflected. The processing container 404 has a sufficient size to accommodate the substrate W. The processing container 404 itself is grounded. A ceiling of the processing container 404 is open. A transmission plate 408 is air-tightly provided in this opening so as to pass the electromagnetic waves therethrough via a seal member 406 such as an O-ring, which will be described later. As a material of the transmission plate 408, for example, a ceramic material such as quartz or aluminum nitride may be used.

In addition, an opening 410 is provided in a sidewall of the processing container 404. A gate valve 412 is provided in the opening 410 to open/close when an object to be processed, for example, the substrate W, is loaded and unloaded.

A stage 432 is provided inside the processing container 404 to place the substrate W on an upper surface thereof. The stage 432 is supported by a cylindrical support 434 provided upright on a bottom portion of the processing container 404. As a material of the stage 432, a ceramic material such as silicon carbide or aluminum nitride may be used.

Further, the stage 432 is thermally connected to a cooler 438 via a cold link 436. For example, a chiller that circulates a refrigerant solution while constantly controlling a temperature of the refrigerant solution, or the like, may be used as the cooler 438. Further, an electronic cooling element (Peltier element) may be used as the cooler 438. The cooler 438 cools the stage 432 via the cold link 436 and cools the substrate W placed on the stage 432.

In addition, lifter pins 442, which are raised/lowered when loading/unloading the substrate W, are disposed below the stage 432. Three lifter pins 442 (only two are described in the illustrated example) are provided concentrically at an interval of 120 degrees, and are supported on lifting bases 444 molded in an arc shape, respectively. The lifting base 444 is connected to a lifting rod 446 that penetrates the bottom portion of the processing container 404 such that the lifter pins 442 are capable of being raised/lowered as described above by an actuator (not illustrated). Further, an extendible metal bellows 448 is provided at a portion through which the lifting rod 446 passes, so as to maintain a sealing property of an interior of the processing container 404.

In addition, an electromagnetic wave introduction means 450 that irradiates electromagnetic waves toward the substrate W is provided above the transmission plate 408 of the processing container 404. Here, the electromagnetic waves may have a frequency in a range of 0.5 GHz to 5 THz. In this embodiment, a case where electromagnetic waves in a microwave region of 28 GHz are used will be described as an example.

Specifically, the electromagnetic wave introduction means 450 includes an incident antenna 452 provided on an upper surface of the transmission plate 408, and an electromagnetic wave generation source 454 that is capable of generating electromagnetic waves having, for example, a frequency in a range of 0.5 GHz to 5 THz. Further, the electromagnetic wave generation source 454 and the incident antenna 452 are connected to each other via a waveguide 456. As the electromagnetic wave generation source 454, for example, a gyrotron, a magnetron, a klystron, a traveling-wave tube, or the like may be used. Specifically, the electromagnetic wave generation source 454 may use electromagnetic waves having a frequency of 28 GHz as described above, and in addition, may use electromagnetic waves having a frequency of 77 GHz, 82.7 GHZ, 107 GHz, 110 GHz, 140 GHz, 168 GHZ, 171 GHZ, 203 GHZ, 300 GHz, 874 GHz, or the like.

In addition, the electromagnetic waves output from the electromagnetic wave generation source 454 are guided to the incident antenna 452 provided on the transmission plate 408 by the waveguide 456 constituted with, for example, a rectangular waveguide, a corrugated waveguide, or the like. Further, the incident antenna 452 is provided with a plurality of specular reflection lenses or reflection mirrors (not illustrated) and is configured to reflect and introduce the guided electromagnetic waves toward and into a processing space S inside the processing container 404.

Even in this case, the reflected electromagnetic waves pass through the transmission plate 408, are introduced into the processing space S, and are irradiated directly onto the substrate surface of the substrate W. This makes it possible to heat the substrate W.

In addition, all operations of the microwave irradiation apparatus 300B are controlled by an apparatus controller 458 constituted with, for example a microcomputer or the like. Programs of the computer, which executes the operations, are stored in a storage medium 460 such as a flexible disk, a compact disc (CD), a flash memory, or a hard disk. Specifically, according to instructions provided from the apparatus controller 458, the supply of a gas, the control of a flow rate of the gas, the supply of the electromagnetic waves, the control of power, the control of a process temperature or a process pressure, and the like are executed.

### First Embodiment

Next, a substrate processing method according to a first embodiment in which a metal pattern of a metal layer 690 is formed on the substrate surface of the substrate W using the substrate processing system 100, will be described with reference to FIGS. 5 to 6C. FIG. 5 is an example of a flowchart illustrating substrate processing according to the first embodiment (and a second embodiment to be described later). FIGS. 6A to 6C are examples of schematic cross-sectional views of the substrate W in each Operation of the substrate processing according to the first embodiment (and the second embodiment to be described later).

In Operation S101, the substrate W is prepared. Here, FIG. 6A shows the substrate W prepared in Operation S101. The substrate W includes a conductor 610 and an insulator 620. For example, a recess such as a trench or via hole is formed in the insulator 620 of the substrate W. The conductor 610 is embedded in the recess of the insulator 620. Accordingly, the substrate surface of the substrate W has a conductor surface 610s to which the conductor 610 is exposed and an insulator surface 620s to which the insulator 620 is exposed. That is, patterns of the conductor 610 and the insulator 620 are formed on the substrate surface of the substrate W.

As the conductor 610, a metal or a semiconductor may be used. Further, a semiconductor which is doped with a high concentration of impurity to increase a charge carrier concentration may be used as the semiconductor. In the following description, a case where the conductor 610 is Ru will be described as an example. As the insulator 629, for example, a SiO₂ film, a SiN film, a SiOCN film, or the like may be used.

In Operation S102, the coating apparatus 200 coats the substrate surface of the substrate W with an ionic liquid 650. FIG. 6B shows the substrate W having the substrate surface coated with the ionic liquid 650 in Operation S102. A metal salt (metal compound) 651 including a metal to be precipitated and a reductant 652 are added to the ionic liquid 650.

The ionic liquid 650 is used as a solvent of the metal salt 651 and the reductant 652. For example, Emim-Al₂Cl₇ including 1-ethyl-3-methylimidazolume (Emim) as a cation and Al₂Cl₇ as an anion may be used. Further, the ionic liquid 650 may use, for example, Emim-AlCl₄ including Emim as a cation and AlCl₄ as an anion. Further, for example, Bmim-PF₆ including 1-butyl-3-methyl-1H-imidazol-3-ium (Bmim) as a cation and PF₆ as an anion may be used as the ionic liquid 650. Further, for example, Bmim-BF₄ including Bmim as a cation and BF₄ as an anion may be used as the ionic liquid 650.

The metal salt 651 added to the ionic liquid 650 is a salt including a metal to be precipitated. The metal salt 651 is ionized into metal ions (cations) and anions in the ionic liquid 650. As the metal salt 651, for example, any one of RuCl₃, NbCl₅, TaCl₅, TiI₄, TiCl₄, ZrI₄, ZrCl₄, Hfl₄, HFCl₄, WCl₆, MoCl₆, and the like may be used.

The reductant 652 added to the ionic liquid 650 reduces the metal (metal ions) in the metal salt 651. As the reductant 652, for example, SnCl₂, WCI₅, VCl₂, TiCl₂, GeCl₂, or the like may be used.

In Operation S103, the energy supply apparatus 300 applies energy to the substrate W to heat the substrate W. Accordingly, the metal (metal ions) in the metal salt 651 is reduced by the reductant 652 so that the metal layer 690 is precipitated on the conductor surface 610s. Further, a reaction by-product 653 is generated. FIG. 6C shows a state of the substrate W in Operation S103.

In the substrate processing method according to the first embodiment, the substrate heating apparatus 300A is used as the energy supply apparatus 300 to supply heat as the energy applied to the substrate W. That is, in the substrate processing method according to the first embodiment, the entire substrate W is heated from the outside. Further, the substrate W is heated to a temperature in a range of 150 degrees C. to 400 degrees C., more preferably 200 degrees C. to 350 degrees C.

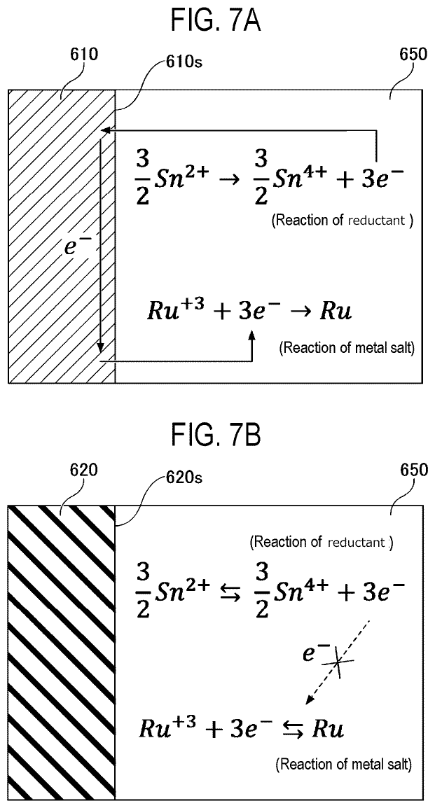

FIGS. 7A and 7B are schematic views illustrating a reaction between the metal salt 651 and the reductant 652. FIG. 7A shows the reaction in a vicinity of the conductor surface 610s. FIG. 7B shows the reaction in a vicinity of the insulator surface 620s and in the ionic liquid 650.

The substrate W coated with the ionic liquid 650 including the metal salt 651 and the reductant 652 is heated by the energy supply apparatus 300 (the substrate heating apparatus 300A), so that the metal ions in the metal salt 651 is caused to react (reduction-react) with the reductant 652 and the metal ions are reduced, thereby precipitating the metal.

Here, a case where RuCl₃ is used as the metal salt 651 and SnCl₂ is used as the reductant 652 will be described as an example. The reductant 652 releases electrons as Sn²⁺ to Sn⁴⁺, and the electrons are supplied to Ru³⁺ of the metal salt 651, so that Ru as the metal is precipitated. In the vicinity of the conductor surface 610s, the electrons released from the reductant 652 are supplied to Ru³⁺ of the metal salt 651 via the conductor 610. Accordingly, in the vicinity of the conductor surface 610s, although the metal salt 651 and the reductant 652 do not come close to each other, the electrons may move via the conductor 610. Thus, the metal (Ru) is precipitated on the conductor surface 610s, so that the metal layer 690 (see FIG. 6C) is formed. Further, SnCl₄ is produced as the reaction by-product 653.

Further, as illustrated in FIG. 7B, in the vicinity of a surface of the insulator 620 and in the ionic liquid 650, when the metal salt 651 and the reductant 652 do not come close to each other, the movement of the electrons is suppressed. Therefore, in the vicinity of the surface of the insulator 620 and in the ionic liquid 650, the precipitation of the metal in the metal salt 651 is suppressed.

As shown by comparing FIGS. 7A and 7B, in the conductor surface 610s, the electrons move via the conductor 610, so that the metal (Ru) is precipitated on the conductor surface 610s. On the other hand, in the vicinity of the surface of the insulator 620 and in the ionic liquid 650, the precipitation of the metal (Ru) is suppressed. Accordingly, the metal (Ru) is selectively precipitated on the conductor surface 610s with respect to the insulator surface 620s, thereby forming the metal layer 690 on the conductor 610. Thus, the metal pattern of the metal layer 690 may be formed on the substrate surface of the substrate W in conformity to the pattern of the conductor 610. Further, the precipitation of the metal in the ionic liquid 650 may be suppressed. Accordingly, it is possible to suppress particles from being generated due to the metal precipitated in the ionic liquid 650.

In addition, by heating the substrate W to a temperature in a range of 150 degrees C. to 400 degrees C., more preferably 200 degrees C. to 350 degrees C., it is possible to promote the precipitation of the metal in the vicinity of the surface of the conductor 610 and to suppress the precipitation of the metal in the vicinity of the surface of the insulator 620 and in the ionic liquid 650.

Here, a speed at which the metal is precipitated may be further increased by removing an oxide film (natural oxide film) existing in an uppermost surface of the conductor 610 and maintaining a metallic active state. As a method of removing the oxide film, a method of generating hydrogen plasma in the vicinity of the substrate surface and etching away the oxide film formed in the uppermost surface of the conductor 610 by a reducing action of the hydrogen plasma, or the like may be used. This processing may include a removal processing operation in a separate apparatus before preparing the substrate W in Operation S101.

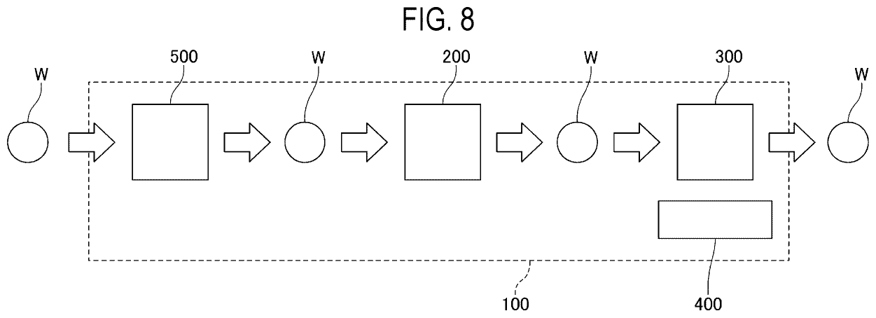

FIG. 8 is a schematic view illustrating another example of the configuration of the substrate processing system 100 according to this embodiment. The substrate processing system 100 includes the coating apparatus 200, the energy supply apparatus 300, the control device 400, and an oxide film removing apparatus 500. The oxide film removing apparatus 500 is provided in front of the coating apparatus 200, which coats the substrate surface of the substrate W with the ionic liquid and performs the removal processing operation of removing the oxide film formed in the uppermost surface of the conductor 610 of the substrate W. As described above, the oxide film removing apparatus 500 may be provided inside the substrate processing system 100, thereby performing coherent processing as necessary.

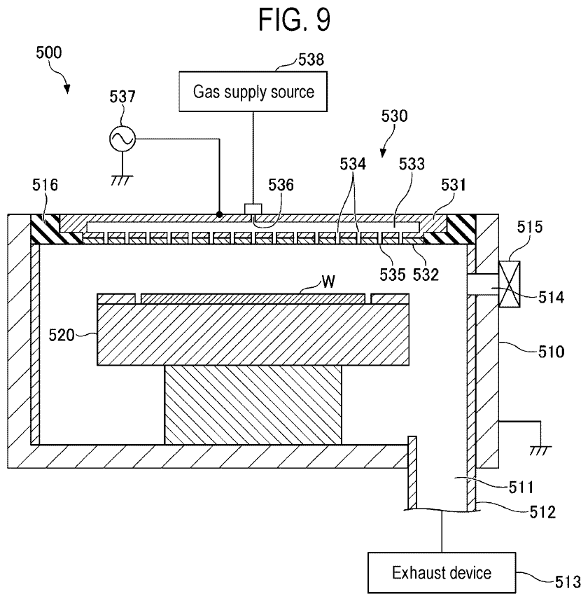

Next, an example of the oxide film removing apparatus 500 will be described with reference to FIG. 9. FIG. 9 is a schematic view illustrating the example of the oxide film removing apparatus 500. As the example of the oxide film removing apparatus 500, a capacitively coupled parallel plate type plasma processing apparatus will be described.

The oxide film removing apparatus 500 includes a processing container 510 which is formed of, for example, aluminum or the like whose surface is anodized, and has a substantially cylindrical space formed therein. Further, the processing container 510 is grounded.

A substantially cylindrical stage 520 on which the substrate W is placed is provided inside the processing container 510. The stage 520 is formed of, for example, aluminum or the like. The stage 520 is supported on a bottom portion of the processing container 510 via an insulator.

An exhaust port 511 is provided in the bottom portion of the processing container 510. An exhaust device 513 is connected to the exhaust port 511 via an exhaust pipe 512. The exhaust device 513 includes, for example, a vacuum pump such as a turbo molecular pump, to depressurize an interior of the processing container 510 to a preset level of vacuum.

An opening 514 through which the substrate W is loaded and unloaded is formed in a sidewall of the processing container 510. The opening 514 is opened/closed by a gate valve 515.

A shower head 530 is provided above the stage 520 to face the stage 520. The shower head 530 is supported by an upper portion of the processing container 510 via an insulating member 516. The stage 520 and the shower head 530 are provided inside the processing container 510 to be substantially parallel to each other.

The shower head 530 includes a ceiling plate holder 531 and a ceiling plate 532. The ceiling plate holder 531 is formed of, for example, aluminum or the like whose surface is anodized, and detachably supports the ceiling plate 532 at a lower portion thereof.

A diffusion chamber 533 is formed in the ceiling plate holder 531. An introduction port 536 communicating with the diffusion chamber 533 is formed in an upper portion of the ceiling plate holder 531. A plurality of flow paths 534 communicating with the diffusion chamber 533 are formed in a bottom portion of the ceiling plate holder 531. A gas source 538 is connected to the introduction port 536 via a pipe. The gas source 538 is a source of a processing gas such as hydrogen gas.

A plurality of through-holes 535 is formed in the ceiling plate 532 to penetrate the ceiling plate 532 in a thickness direction. One through-hole 535 is in communication with one flow path 534. The processing gas supplied into the diffusion chamber 533 from the gas source 538 via the introduction port 536 diffuses inside the diffusion chamber 533 and is supplied into the processing container 510 in the form of a shower via the plurality of flow paths 534 and the plurality of through-holes 535.

A radio-frequency power source 537 is connected to the ceiling plate holder 531 of the shower head 530. The radio-frequency power source 537 supplies radio frequency power having a preset frequency to the ceiling plate holder 531. The frequency of the radio frequency power is, for example, a frequency in a range of 450 kHz to 2.5 GHz. The radio frequency power supplied to the ceiling plate holder 531 is radiated into the processing container 510 from a lower surface of the ceiling plate holder 531. The processing gas supplied into the processing container 510 is plasmarized by the radio frequency power radiated into the processing container 510. Further, ions, active species, or the like, which are included in the plasma, are irradiated onto the substrate surface of the substrate W.

As described above, the oxide film removing apparatus 500 generates the hydrogen plasma in the processing container 510, exposes the substrate W placed on the stage 520 to the hydrogen plasma, and removes the oxide film formed in the uppermost surface of the conductor 610 by the reducing action of the hydrogen plasma.

### Second Embodiment

Next, a substrate processing method according to a second embodiment in which the substrate processing system 100 is used to form the metal pattern of the metal layer 690 on the substrate surface of the substrate W, will be described with reference to FIGS. 5 to 6C. The substrate processing method according to the second embodiment differs from the substrate processing method according to the first embodiment (see FIGS. 5 to 6C) in that the energy supply apparatus 300 is used in Operation S103. Other Operations S101 and S102 are similar to Operations S101 and S102 in the substrate processing method according to the first embodiment, and redundant descriptions thereof will be omitted.

In Operation S103, the energy supply apparatus 300 supplies energy to the substrate W to heat the substrate W. Thus, the metal (metal ions) in the metal salt 651 is reduced by the reductant 652, and the metal layer 690 is precipitated on the conductor surface 610s.

In the substrate processing method according to the second embodiment, the microwave irradiation apparatus 300B is used as the energy supply apparatus 300 to supply microwaves as the energy applied to the substrate W. The microwaves irradiated onto the substrate W from the microwave irradiation apparatus 300B pass through the insulator 620 and have a frequency which may be absorbed by the conductor 610. Accordingly, the microwave irradiation apparatus 300B irradiates the microwaves onto the substrate W to selectively heat the conductor 610 with respect to the insulator 620. That is, in the substrate processing method according to the second embodiment, the conductor 610 of the substrate W is heated from an interior thereof.

With this configuration, a precipitation reaction of the metal in the vicinity of the conductor surface 610s may be prompted and the metal of the metal salt 651 may be selectively precipitated on the conductor surface 610s with respect to the insulator surface 620s, thereby forming the metal layer 690 on the conductor 610. Further, the precipitation of the metal in the ionic liquid 650 may be suppressed.

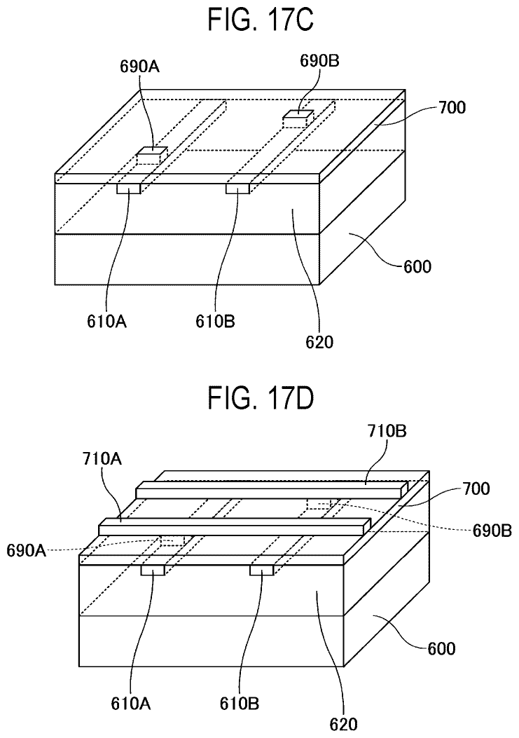

In addition, the microwave irradiation apparatus 300B may cool the entire substrate W by the cooler 438. Accordingly, a difference in temperature between the conductor 610 and the insulator 620 may be increased. Thus, by selectively precipitating the metal of the metal salt 651 on the conductor surface 610s with respect to the insulator surface 620s, it is possible to form the metal layer 690 on the conductor 610. Further, the conductor 610 and the insulator 620 are formed on, for example, a silicon substrate 600 (see FIGS. 17A to 17D to be described later). By cooling the silicon substrate 600, a concentration of carriers in the silicon substrate 600 may be suppressed and induction heating of the silicon substrate 600 may be suppressed. Accordingly, it is possible to selectively heat the conductor 610.

### Third Embodiment

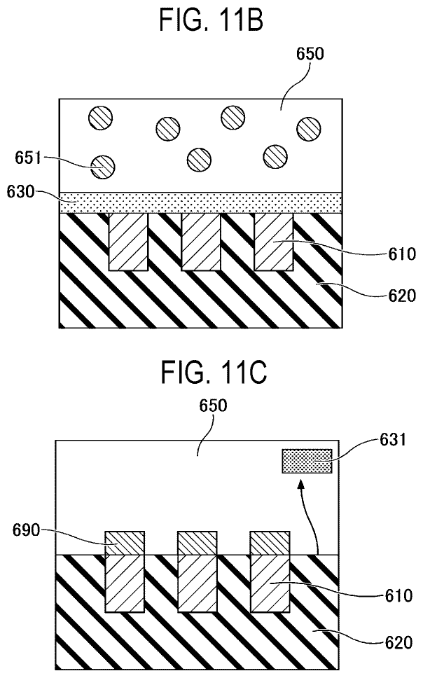

Next, a substrate processing method according to a third embodiment in which the substrate processing system 100 is used to form the metal pattern of the metal layer 690 on the substrate surface of the substrate W, will be described with reference to FIGS. 10 to 11C. FIG. 10 is an example of a flowchart illustrating substrate processing according to the third embodiment (and a fourth embodiment to be described later). FIGS. 11A to 11C are examples of schematic cross-sectional views of the substrate W in each Operation of the substrate processing according to the third embodiment (and the fourth embodiment to be described later).

In Operation S301, the substrate W is prepared. The substrate W prepared in Operation S301 is similar to the substrate W shown in FIG. 6A.

In Operation S302, a reductant 630 is disposed on the substrate surface of the substrate W. FIG. 11A shows the substrate W having the reductant 630 disposed on the substrate surface of the substrate W in Operation S302. The reductant 630 includes a metal which is more easily ionized than the metal of the metal salt 651 (having a large ionization tendency). As the metal included in the reductant 630, for example, Mg, Al, Sr, Li, Ti, or the like may be used. The reductant 630 may be disposed (formed) on the substrate surface of the substrate W by, for example, a film forming method using a physical vapor deposition (PVD) method, a film forming method using an atomic layer deposition (ALD) method, a film forming method using a chemical vapor deposition (CVD) method, or the like. Further, the reductant 630 may be disposed on the substrate surface of the substrate W by coating.

In Operation S303, the coating apparatus 200 coats the substrate surface of the substrate W with the ionic liquid 650. FIG. 11B shows the substrate W having the ionic liquid 650 coated on the substrate surface of the substrate W in Operation S303. The metal salt (metal compound) 651 including a metal to be precipitated is added to the ionic liquid 650.

The ionic liquid 650 is used as a solvent of the metal salt 651. As the ionic liquid 650, any one of Emim-Al₂Cl₇, Emim-AlCl₄, Bmim-PF₆, Bmim-BF₄, and the like may be used.

The metal salt 651 added to the ionic liquid 650 is a salt including a metal to be precipitated. The metal salt 651 is ionized into metal ions (cations) and anions in the ionic liquid 650. As the metal salt 651, for example, any one of RuCl₃, NbCl₅, TaCl₅, TiI₄, TiCl₄, ZrI₄, ZrCl₄, Hfl₄, HFCl₄, WCl₆, MoCl₆, and the like may be used.

In Operation S304, the energy supply apparatus 300 applies energy to the substrate W to heat the substrate W. Accordingly, the metal (metal ions) in the metal salt 651 is reduced by the reductant 630 so that the metal layer 690 is precipitated on the conductor surface 610s. FIG. 11C shows a state of the substrate W in Operation S304. Further, in FIG. 11C, illustration of the reaction by-product 653 is omitted.

In the substrate processing method according to the third embodiment, the substrate heating apparatus 300A is used as the energy supply apparatus 300 to supply heat as the energy to be applied to the substrate W. That is, in the substrate processing method according to the third embodiment, the entire substrate W is heated from the outside. Further, the substrate W is heated to a temperature in a range of 150 degrees C. to 400 degrees C., more preferably 200 degrees C. to 350 degrees C.

The metal salt 651 and the reductant 630 react with each other by heating the substrate W, so that the reductant 630 dissolves. In this case, by a difference in adhesion between the reductant 630 and the substrate surface (the conductor surface 610s and the insulator surface 620s), the reductant 630 disposed on the insulator surface 620s is separated from the substrate surface to become a reductant 631. Further, the reductant 630 on the conductor surface 610s reacts with the metal salt 651 in the ionic liquid 650 and is replaced with the metal of the metal salt 651, so that the metal of the metal salt 651 is precipitated on the conductor surface 610s. Accordingly, by selectively precipitating the metal of the metal salt 651 on the conductor surface 610s with respect to the insulator surface 620s, it is possible to form the metal layer 690 on the conductor 610.

Thus, the metal pattern of the metal layer 690 may be formed on the substrate surface of the substrate W in conformity to the pattern of the conductor 610. Further, the precipitation of the metal in the ionic liquid 650 may be suppressed.

### Fourth Embodiment

Next, a substrate processing method according to the fourth embodiment in which the substrate processing system 100 is used to form the metal pattern of the metal layer 690 on the substrate surface of the substrate W, will be described with reference to FIGS. 10 to 11C. The substrate processing method according to the fourth embodiment differs from the substrate processing method according to the third embodiment (see FIGS. 10 to 11C) in that the energy supply apparatus 300 used in Operation S304 is different. Other Operations S301 to S303 are similar to Operations S301 to S303 in the substrate processing method according to the third embodiment, and redundant descriptions thereof will be omitted.

In Operation S304, the energy supply apparatus 300 applies energy to the substrate W to heat the substrate W. Accordingly, the metal (metal ions) of the metal salt 651 is reduced by the reductant 630 so that the metal layer 690 is precipitated on the conductor surface 610s.

In the substrate processing method according to the fourth embodiment, the microwave irradiation apparatus 300B is used as the energy supply apparatus 300 to supply microwaves as the energy to be applied to the substrate W. The microwaves irradiated onto the substrate W from the microwave irradiation apparatus 300B pass through the insulator 620 and have a frequency which may be absorbed to the conductor 610. Accordingly, the microwave irradiation apparatus 300B may irradiate the microwaves onto the substrate W to selectively heat the conductor 610 with respect to the insulator 620. That is, in the substrate processing method according to the fourth embodiment, the conductor 610 of the substrate W is heated from an interior thereof.

Accordingly, by promoting the precipitation reaction of the metal in the vicinity of the conductor surface 610s and selectively precipitating the metal of the metal salt 651 on the conductor surface 610s with respect to the insulator surface 620s, it is possible to form the metal layer 690 on the conductor 610. Further, the precipitation of the metal in the ionic liquid 650 may be suppressed.

In addition, the microwave irradiation apparatus 300B may cool the entire substrate W by the cooler 438. Accordingly, a difference in temperature between the conductor 610 and the insulator 620 may be increased. This makes it possible to selectively precipitate the metal of the metal salt 651 on the conductor surface 610s with respect to the insulator surface 620s, and form the metal layer 690 on the conductor 610. Further, the conductor 610 and the insulator 620 are formed on, for example, the silicon substrate 600 (see FIGS. 17A to 17D to be described later). By cooling the silicon substrate 600, a concentration of carriers in the silicon substrate 600 may be suppressed, thereby suppressing induction heating of the silicon substrate 600. Accordingly, the conductor 610 may be selectively heated.

### Fifth Embodiment

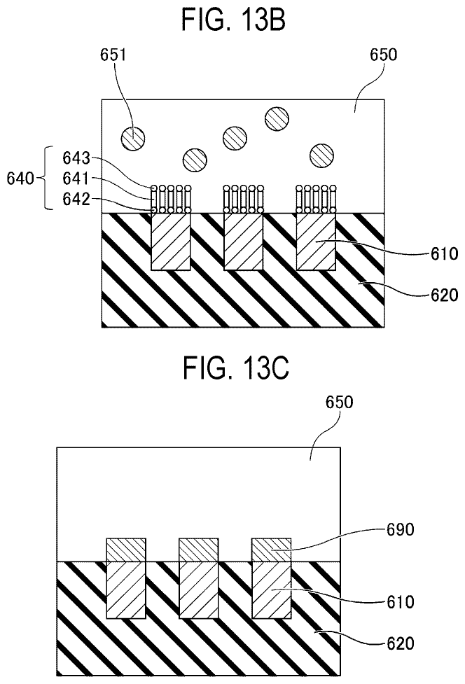

Next, a substrate processing method according to a fifth embodiment in which the substrate processing system 100 is used to form the metal pattern of the metal layer 690 on the substrate surface of the substrate W, will be described with reference to FIGS. 12 to 13C. FIG. 12 is an example of a flowchart illustrating substrate processing according to the fifth embodiment (and a sixth embodiment to be described later). FIGS. 13A to 13C are examples of schematic cross-sectional views of the substrate W in each Operation of the substrate processing according to the fifth embodiment (and the sixth embodiment to be described later).

In Operation S501, the substrate W is prepared. The substrate W prepared in Operation S501 is similar to the substrate W shown in FIG. 6A.

In Operation S502, an organic compound 640 is disposed as a reductant on the conductor surface 610s. FIG. 13A shows the substrate W having the organic compound 640 disposed on the substrate surface of the substrate W in Operation S502. The organic compound 640 includes a main chain (chain portion) 641, a first functional group 642 formed at one end of the main chain 641, and a second functional group 643 formed at the other end of the main chain 641.

The main chain 641 is formed by bonding carbons (C) to each other. The main chain 641 is formed with, for example, an alkyl chain.

The first functional group 642 is a functional group selectively adsorbed (bonded) to the conductor 610. The first functional group 642 includes, for example, at least one of thiol, carboxylic acid, sulfonic acid, phosphoric acid, olefin, or the like.

The second functional group 643 is a functional group that reduces the metal (metal ions) of the metal salt 651. As the second functional group 643, for example, an amino group may be used.

In addition, any one of 3-aminopropyltriethoxysilane, 3-(dimethoxymethylsilyl) propylamine, and the like may be used as the organic compound 640.

For example, gas of the organic compound 640 is supplied into the processing container (not illustrated) so that the substrate surface of the substrate W is exposed to the organic compound 640. Accordingly, the first functional group 642 is selectively adsorbed to the conductor 610, so that the organic compound 640 is selectively disposed on the conductor surface 610s with respect to the insulator surface 620s. The organic compound 640 adsorbed to the conductor surface 610s forms a self-assembled monolayer (SAM).

In Operation S503, the coating apparatus 200 coats the substrate surface of the substrate W with the ionic liquid 650. FIG. 13B shows the substrate W having the ionic liquid 650 coated on the substrate surface of the substrate W in Operation S503. The metal salt (metal compound) 651 including a metal to be precipitated is added to the ionic liquid 650.

The ionic liquid 650 is used as a solvent of the metal salt 651. As the ionic liquid 650, any one of Emim-Al₂Cl₇, Emim-AlCl₄, Bmim-PF₆, Bmim-BF₄, and the like may be used.

The metal salt 651 added to the ionic liquid 650 is a salt including a metal to be precipitated. The metal salt 651 is ionized into metal ions (cations) and anions in the ionic liquid 650. As the metal salt 651, for example, any one of RuCl₃, NbCl₅, TaCl₅, TiI₄, TiCl₄, ZrI₄, ZrCl₄, Hfl₄, HFCl₄, WCl₆, MoCl₆, and the like may be used.

In Operation S504, the energy supply apparatus 300 applies energy to the substrate W to heat the substrate W. Accordingly, the metal (metal ions) of the metal salt 651 is reduced by the second functional group 643 (the amino group), so that the metal layer 690 is precipitated on the conductor surface 610s. FIG. 13C shows a state of the substrate W in Operation S504. Further, in FIG. 13C, illustration of the reaction by-product 653 is omitted.

In the substrate processing method according to the fifth embodiment, the substrate heating apparatus 300A is used as the energy supply apparatus 300 to supply heat as the energy to be applied to the substrate W. That is, in the substrate processing method according to the fifth embodiment, the entire substrate W is heated from the outside. Further, the substrate W is heated to a temperature in a range of 150 degrees C. to 400 degrees C., more preferably 200 degrees C. to 350 degrees C.

The metal salt 651 and the second functional group 643 (the amino group) that functions as the reductant react with each other, so that the metal of the metal salt 651 is precipitated on the conductor surface 610s. Accordingly, by selectively precipitating the metal of the metal salt 651 on the conductor surface 610s with respect to the insulator surface 620s, it is possible to form the metal layer 690 on the conductor 610.

Thus, the metal pattern of the metal layer 690 may be formed on the substrate surface of the substrate W in conformity to the pattern of the conductor 610. Further, the precipitation of the metal in the ionic liquid 650 may be suppressed.

### Sixth Embodiment

Next, a substrate processing method according to the sixth embodiment in which the substrate processing system 100 is used to form the metal pattern of the metal layer 690 on the substrate surface of the substrate W, will be described with reference to FIGS. 12 to 13C. The substrate processing method according to the sixth embodiment differs from the substrate processing method according to the fifth embodiment (see FIGS. 12 to 13C) in that the energy supply apparatus 300 used in Operation S504 is different. Other Operations S501 to S503 are similar to Operations S501 to S503 in the substrate processing method according to the fifth embodiment, and redundant descriptions thereof will be omitted.

In Operation S504, the energy supply apparatus 300 applies energy to the substrate W to heat the substrate W. Accordingly, the metal (metal ions) of the metal salt 651 is reduced by the second functional group 643 (the amino group), so that the metal layer 690 is precipitated on the conductor surface 610s.

In the substrate processing method according to the sixth embodiment, the microwave irradiation apparatus 300B is used as the energy supply apparatus 300 to supply microwaves as the energy to be applied to the substrate W. In this case, the microwaves irradiated onto the substrate W from the microwave irradiation apparatus 300B pass through the insulator 620 and have a frequency which may be absorbed to the conductor 610. Accordingly, the microwave irradiation apparatus 300B may irradiate the microwaves onto the substrate W to selectively heat the conductor 610 with respect to the insulator 620. That is, in the substrate processing method according to the sixth embodiment, the conductor 610 of the substrate W is heated from an interior thereof.

Accordingly, by promoting the precipitation reaction of the metal in the vicinity of the conductor surface 610s and selectively precipitating the metal of the metal salt 651 on the conductor surface 610s with respect to the insulator surface 620s, it is possible to form the metal layer 690 on the conductor 610. Further, the precipitation of the metal in the ionic liquid 650 may be suppressed.

In addition, the microwave irradiation apparatus 300B may cool the entire substrate W by the cooler 438. Accordingly, a difference in temperature between the conductor 610 and the insulator 620 may be increased. Thus, by selectively precipitating the metal of the metal salt 651 on the conductor surface 610s with respect to the insulator surface 620s, it is possible to form the metal layer 690 on the conductor 610. Further, the conductor 610 and the insulator 620 are formed on, for example, the silicon substrate 600 (see FIGS. 17A to 17D to be described later). By cooling the silicon substrate 600, a concentration of carriers in the silicon substrate 600 may be suppressed, and induction heating of the silicon substrate 600 may be suppressed. Accordingly, the conductor 610 may be selectively heated.

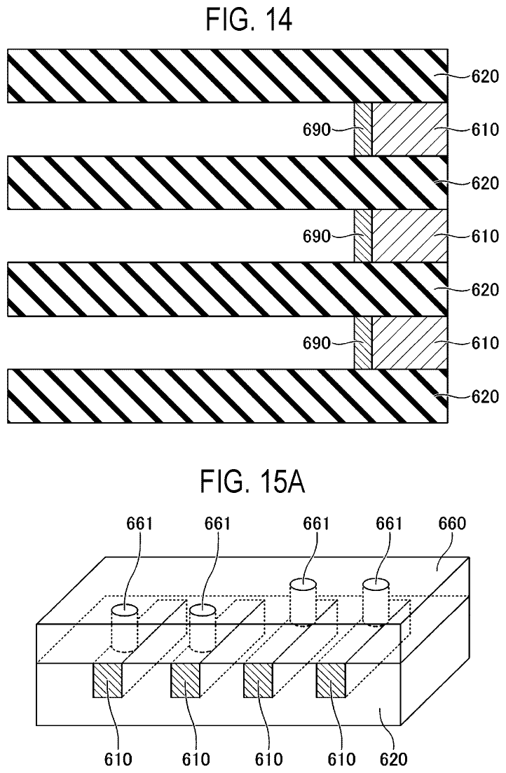

Next, examples in which the substrate processing according to the present embodiments (the first to sixth embodiments) is used will be described with reference to FIGS. 14 to 17D.

FIG. 14 is a schematic cross-sectional view illustrating an example of a structure formed in the substrate W. The substrate W includes the conductor 610 and the insulator 620. The insulator 620 has a recess formed in a horizontal direction, and the conductor 610 is formed inward of the recess. The conductor 610 is, for example, Si, and the insulator 620 is, for example, SiO₂. In this structure, by using the substrate processing methods according to the first to sixth embodiments, it is possible to form the metal layer 690 on the surface of the conductor 610.

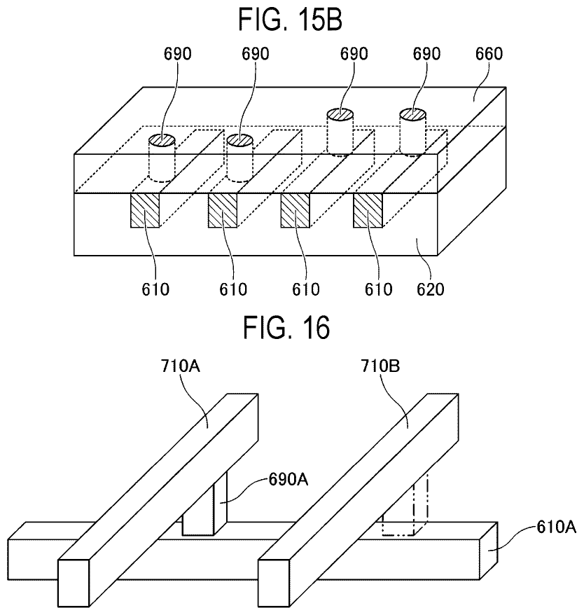

FIGS. 15A and 15B are perspective views illustrating another example of the structure formed in the substrate W. As illustrated in FIG. 15A, the substrate W is provided with a first layer including the conductor 610 and the insulator 620, and a second layer 660 formed on the first layer. The second layer 660 is formed of an insulator, and has a hole 661 formed to penetrate the conductor 610 of the first layer. As illustrated in FIG. 15B, the metal layer 690 is embedded in the hole 661. In this structure, by using the substrate processing methods according to the first to sixth embodiments, it is possible to embed the metal layer 690 into the hole 661.

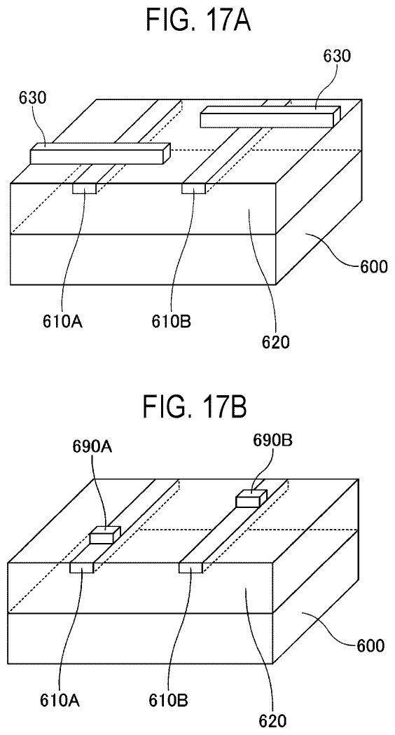

FIG. 16 is a perspective view illustrating an example of a structure of a metal wiring formed in the substrate W. A conductor 710A and a conductor 710B are disposed on a conductor 610A. A metal layer 690A electrically connects the conductor 610A and the conductor 710A. Further, no metal layer (indicated by an alternate long and two short dashes line in FIG. 16) is provided at a position between the conductor 610A and the conductor 710B.

Next, processing of forming the structure of the metal wiring shown in FIG. 16 in the substrate W will be described with reference to FIGS. 17A to 17D. FIGS. 17A to 17D are examples of perspective views of the substrate W in each Operation.

First, the substrate W is prepared (see Operation S301). As illustrated in FIG. 17A, the prepared substrate W includes the insulator 620 and conductors 610A and 620A formed parallel to each other, which are formed on the silicon substrate 600.

Subsequently, the reductant 630 is disposed on the substrate surface of the substrate W (see Operation S302). As illustrated in FIG. 17A, the pattern of the reductant 630 is formed on the substrate surface of the substrate W. The reductant 630 includes a metal which is more easily ionized than the metal of the metal salt 651 (having a large ionization tendency). The reductant 630 is formed to intersect the conductors 610A and 610B.

Subsequently, the coating apparatus 200 coats the substrate surface of the substrate W with the ionic liquid 650 (see Operation S303). Next, the energy supply apparatus 300 applies energy to the substrate W to heat the substrate W (see Operation S304). When the substrate W is heated, the reductant 630 dissolves. In this case, due to a difference between the adhesion of the reductant 630 to the conductors 610A and 610B and the adhesion of the reductant 630 to the insulator 620, the reductant 630 disposed on the surface of the insulator 620 is separated from the substrate surface. Further, the reductant 630 disposed on the surfaces of the conductors 610A and 610B reacts with the metal salt 651 in the ionic liquid 650 and is replaced with the metal of the metal salt 651, so that the metal of the metal salt 651 is precipitated on the conductor surface 610s. Accordingly, as illustrated in FIG. 17B, metal layers 690A and 690B are formed at positions at which the conductors 610A and 610B and the reductant 630 intersect each other.

Next, an insulator 700 is formed on the substrate surface of the substrate W. Further, the substrate surface of the substrate W is polished by CMP processing to expose upper surfaces of the metal layers 690A and 690B. Thus, as illustrated in FIG. 17C, the metal layers 690A and 690B and the insulator 700 are formed.

Next, patterns of the conductors 710A and 710B are formed on the substrate surface of the substrate W. Thus, as illustrated in FIG. 17D, the patterns of the conductors 710A and 710B are formed on the substrate surface of the substrate W. Thus, a wiring structure (see FIG. 16) in which the conductor 610A and the conductor 710A are electrically connected to each other via the metal layer 690A is formed in the substrate W. Further, a wiring structure in which the conductor 610B and the conductor 710B are electrically connected to each other via the metal layer 690B is formed in the substrate W.

As described above, through Operations described with reference to FIGS. 17A to 17D, the structure of the metal wiring as shown in FIG. 16 may be formed in the substrate W.

According to the present disclosure in some embodiments, it is possible to provide a substrate processing method and a substrate processing system which form a metal layer on a surface of a conductor of a substrate in which patterns of the conductor and an insulator are formed.

The embodiments disclosed herein should be considered to be exemplary and not limitative in all respects. The above embodiments may be omitted, replaced, and modified in various ways without departing from the scope and spirit of the appended claims.

What is claimed is:

1. A substrate processing method, comprising:
preparing a substrate in which patterns of a conductor and an insulator are formed in a substrate surface of the substrate;
coating the substrate surface of the substrate with an ionic liquid including a metal salt; and
applying energy to the substrate coated with the ionic liquid,
wherein the applying the energy to the substrate includes forming a metal layer on a surface of the conductor by precipitating a metal of the metal salt on the surface of the conductor by a reduction reaction of the metal salt.

2. The substrate processing method of claim 1, wherein, in the coating the substrate surface of the substrate with the ionic liquid, the ionic liquid coated on the substrate includes a reductant which undergoes the reduction reaction with the metal salt.

3. The substrate processing method of claim 1, further comprising: disposing a reductant on the substrate surface of the substrate after the preparing the substrate and before the coating the substrate surface of the substrate with the ionic liquid.

4. The substrate processing method of claim 3, wherein the reductant includes a metal having a larger ionization tendency than the metal of the metal salt.

5. The substrate processing method of claim 3, wherein the reductant includes:
a main chain;
a first functional group formed at a first end of the main chain to be selectively adsorbed to the conductor; and
a second functional group formed at a second end of the main chain to reduce the metal of the metal salt.

6. The substrate processing method of claim 1, wherein, in the applying the energy to the substrate, the substrate is heated to a temperature in a range of 150 degrees C. to 400 degrees C.

7. The substrate processing method of claim 1, wherein, in the applying the energy to the substrate, the conductor is selectively heated by irradiating microwaves onto the substrate.

8. The substrate processing method of claim 7, wherein, in the applying the energy to the substrate, a stage on which the substrate is placed is cooled.

9. The substrate processing method of claim 1, wherein the conductor is a metal or a semiconductor.

10. The substrate processing method of claim 1, wherein the metal salt is one selected from a group consisting of RuCl₃, NbCl₅, TaCl₅, TiI₄, TiCl₄, ZrI₄, ZrCl₄, Hfl₄, HFCl₄, WCl₆, and MoCl₆.

11. The substrate processing method of claim 2, wherein the reductant is one selected from a group consisting of SnCl₂, WCl₅, VCl₂, TiCl₂, and GeCl₂.

12. The substrate processing method of claim 4, wherein the reductant includes one selected from a group consisting of Mg, Al, Sr, Li, and Ti.

13. The substrate processing method of claim 5, wherein the second functional group is an amino group.

14. A substrate processing system, comprising:
a coating apparatus configured to coat a surface of a substrate with an ionic liquid including a metal salt, wherein a conductor and an insulator are formed on the surface of the substrate; and
an energy supply apparatus configured to apply energy to the substrate coated with the ionic liquid.

15. The substrate processing system of claim 14, wherein the energy supply apparatus is a heating apparatus configured to heat the substrate.

16. The substrate processing system of claim 14, wherein the energy supply apparatus is a microwave irradiation apparatus configured to heat the conductor of the substrate by irradiating microwaves onto the substrate.
